(19) United States
(12) Patent Application Publication
(10) Pub. No.: US 2023/0157175 A1
(43) Pub. Date: May 18, 2023

(54) Power Transistor IC with Thermocouple Having p-Thermopile and n-Thermopile

(71) Applicant: Texas Instruments Incorporated, Dallas, TX (US)

(72) Inventors: Henry Litzmann Edwards, Garland, TX (US); Andres Arturo Blanco, Garland, TX (US); Orlando Lazaro, Cary, NC (US)

(21) Appl. No.: 17/528,990

(22) Filed: Nov. 17, 2021

(51) Int. Cl. H01L 27/16

(52) U.S. Cl. CPC H01L 27/16; H01L 35/32

(57) ABSTRACT

Integrated circuit apparatus, and their manufacturing methods, including an integrated power transistor and thermocouple. The power transistor is constructed in a plurality of layers formed over a semiconductor substrate. The thermocouple includes a p-thermopile and an n-thermopile that are each electrically isolated from the power transistor and the semiconductor substrate while being sensitive to temperature differences within the IC resulting from operation of the power transistor. The p-thermopile includes a p-type thermoelectric body formed in a p-type one or more of the plurality of layers. The n-thermopile includes n-type thermoelectric body formed in an n-type one or more of the plurality of layers.

### TECHNICAL FIELD

The present disclosure relates generally to power transistors in integrated circuits (ICs) and more particularly, but not exclusively, to a power transistor with an integrated thermopile and methods for making the same.

### BACKGROUND OF THE DISCLOSURE

Power field-effect transistor (FET) arrays are subject to high-power and high-temperature stresses that can cause damage. Thermal runaway due to FET self-heating is an example. On-chip temperature sensors based on diodes are often used to prevent such high temperature stress, such as in over-temperature protection circuits. However, ambient or board temperature adds to the chip temperature, so the use of absolute temperature to trigger protection circuits may not accurately respond to thermal runaway.

### SUMMARY OF THE DISCLOSURE

This summary is provided to introduce a selection of concepts that are further described below in the detailed description. This summary is not intended to identify indispensable features of the claimed subject matter, nor is it intended for use as an aid in limiting the scope of the claimed subject matter.

In one example, the present disclosure introduces an IC apparatus including a power transistor and a thermocouple. The power transistor is constructed in a plurality of layers formed over a semiconductor substrate. The thermocouple includes a p-thermopile and an n-thermopile that are each electrically isolated from the power transistor and the semiconductor substrate while being sensitive to temperature differences within the IC resulting from operation of the power transistor. The p-thermopile includes a p-type thermoelectric body formed in a p-type one or more of the plurality of layers. The n-thermopile includes an n-type thermoelectric body formed in an n-type one or more of the plurality of layers.

In another example, an integrated circuit includes a transistor array having a first plurality of transistors on or over a semiconductor substrate. Each transistor is electrically isolated from a neighboring transistor by an isolation structure, and a perimeter of the transistor array is defined by outermost ones of the transistors. A second plurality of thermocouples is also located in or over the semiconductor substrate. Each of the thermocouples has one or more semiconductor thermopiles formed in or over the semiconductor substrate and located within the perimeter of the transistor array.

The present disclosure also introduces methods of manufacturing an IC apparatus comprising a power transistor. In one example, a method includes, simultaneously with constructing the power transistor in a plurality of layers formed over a semiconductor substrate, forming a thermocouple that is electrically isolated from the power transistor and the semiconductor substrate while being sensitive to temperature differences within the IC resulting from operation of the power transistor. Forming the thermocouple includes forming a p-thermopile and an n-thermopile. Forming the p-thermopile includes forming a p-type thermoelectric body in a p-type one or more of the plurality of layers. Forming the n-thermopile includes forming an n-type thermoelectric body in an n-type one or more of the plurality of layers.

In another example, a method of manufacturing an integrated circuit includes forming an array of power transistors in or over a semiconductor substrate. A plurality of thermocouples is formed within the array, each thermocouple electrically isolated from the power transistors and the semiconductor substrate and from others of the thermocouples. The thermocouples are configured to provide an electrical signal responsive to heat flow from an interior portion of the array to a peripheral portion of the array.

These and additional aspects of the present disclosure are set forth in the description that follows, and/or may be learned by a person having ordinary skill in the art by reading the material herein and/or practicing the principles described herein. At least some aspects of the present disclosure may be achieved via means recited in the attached claims.

### BRIEF DESCRIPTION OF THE DRAWINGS

The present disclosure is understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a schematic sectional view of a portion of an example implementation of a power transistor IC apparatus in an intermediate stage of manufacture according to one or more aspects of the present disclosure.

FIG. 2 is a schematic plan view of a portion of an example implementation of a power transistor IC apparatus in an intermediate stage of manufacturing according to one or more aspects of the present disclosure.

FIG. 3 is a schematic sectional view of a portion of an example implementation of a trench-isolated, silicon-to-silicon thermocouple in an intermediate stage of manufacture according to one or more aspects of the present disclosure.

FIG. 4 is a schematic sectional view of a portion of an example implementation of a junction-isolated, silicon thermocouple in an intermediate stage of manufacture according to one or more aspects of the present disclosure.

FIG. 5 is a schematic sectional and perspective view of a portion of an example implementation of a shallow-trench isolated, silicon thermocouple in an intermediate stage of manufacture according to one or more aspects of the present disclosure.

FIG. 6 is a schematic sectional and perspective view of a portion of an example implementation of a shallow-trench isolated, silicon-to-polysilicon thermocouple in an intermediate stage of manufacture according to one or more aspects of the present disclosure.

FIG. 7 is a schematic sectional and perspective view of a portion of an example implementation of a shallow-trench isolated, polysilicon-to-polysilicon thermocouple in an intermediate stage of manufacture according to one or more aspects of the present disclosure.

FIG. 8 is a schematic plan view of a portion of another example implementation of a power transistor IC apparatus in an intermediate stage of manufacturing according to one or more aspects of the present disclosure.

### DETAILED DESCRIPTION

The following disclosure is described with reference to the attached figures. The figures are not drawn to scale, and they are provided merely to illustrate the disclosure. Several aspects of the disclosure are described below with reference to example implementations for illustration. It should be understood that numerous specific details, relationships, and methods are set forth to provide an understanding of the disclosure. However, the following disclosure is not limited by the illustrated ordering of acts or events, some of which may occur in different orders and/or concurrently with other acts or events, yet still fall within the scope of the following disclosure. Moreover, not all illustrated acts or events are required to implement a methodology in accordance with the following disclosure.

In addition, although some of the embodiments illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present disclosure illustrates embodiments directed to example devices, it is not intended that these illustrations be a limitation on the scope or applicability of the various implementations. It is not intended that the example devices of the present disclosure be limited to the physical structures illustrated. These structures are included to demonstrate the utility and application of the present disclosure to example (and perhaps preferred) implementations.

It is also to be understood that the following disclosure may provide different examples for implementing different features of various implementations. Specific examples of components and arrangements are described below to simplify the present disclosure. These are, of course, merely examples and are not intended to be limiting. In addition, the following disclosure may repeat reference numerals and/or letters in more than one implementation. This repetition is for simplicity and clarity and does not in itself dictate a relationship between the various implementations and/or configurations discussed. Moreover, the formation of a first feature over or on a second feature in the description that follows may include implementations in which the first and second features are formed in direct contact and/or implementations in which additional features may be formed interposing the first and second features, such that the first and second features may not be in direct contact.

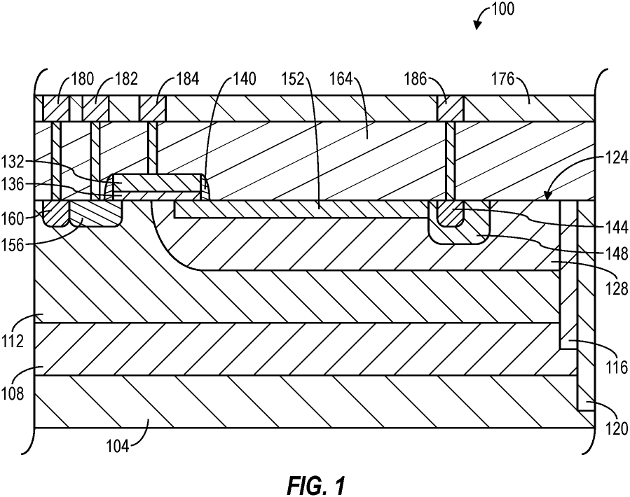

FIG. 1 is a schematic sectional view of a portion of an example implementation of a power transistor IC apparatus in an intermediate stage of manufacture according to one or more aspects of the present disclosure. The power transistor IC apparatus includes a power transistor 100 constructed in a plurality of layers formed over a p-type silicon, gallium arsenide, gallium nitride, silicon carbide, gallium nitride on silicon, and/or other semiconductor substrate (or “die”) 104. The example power transistor 100 is described below as a lateral double-diffused metal-oxide-semiconductor field-effect transistor (LDMOS) built with a source-centered geometry, such as may be utilized as a buck converter high-side n-type power transistor contained within an n-type isolation tank. The power transistor 100 is an example power transistor that can be integrated with a thermocouple according to one or more aspects of the present disclosure. However, thermocouples within the scope of the present disclosure may also be readily adapted for use with other transistors, such as LDMOS implementations other than as depicted in FIG. 1, as well as a metal-oxide-semiconductor field-effect transistor (MOSFET), a drain-extended MOSFET (DEMOS), a metal-insulator-semiconductor field-effect transistor (MISFET), a bipolar junction transistor, and/or other power transistors. Such power transistors may be either p-type or n-type transistors.

The layers formed over the semiconductor substrate 104 include an n-type buried layer (NBL) 108 that is implanted and driven (e.g., by anneal) into the p-type semiconductor substrate 104 to underly the power transistor 100 (or an array of multiple instances of the power transistor 100), thereby also defining a p-type buried layer (PBL) or other p-doped region 112 comprising channel regions of the power transistor 100. The NBL 108 extends laterally to contact a deep n-type region (DEEPN) 116 implanted laterally from a deep trench 120 before the deep trench 120 is filled with dielectric material. The DEEPN 116 vertically extends from at least an upper surface 124 of an n-type deep well (DNWELL) 128 to a bulk portion of the NBL 108, thereby forming an n-type isolation tank surround the power transistor 100. The deep trench 120 vertically extends from at least the upper surface 124 to a bulk portion of the semiconductor substrate 104.

The DNWELL 128 extends laterally from the DEEPN 116 to underneath a gate structure comprising an n-doped polysilicon gate 132 overlying an oxide or other gate dielectric 136 and surrounded by dielectric sidewall spacers 140. An n+ doped drain 144 is implanted within a shallow n-type well (SNW) 148 that is implanted in the DNWELL 128. The drain 144 may instead be implanted directly in the DNWELL 128 absent the SNW 148. A shallow-trench isolation (STI) 152 may be deposited in the DNWELL 128 to extend laterally from the SNW 148 to underneath the gate structure, although other implementations may exclude the STI 152, such as for lower voltage rated LDMOS (e.g., when drain voltage (V_{D}) is less than 12-20 volts (V), depending on details of the implementation). An n+ doped source 156 and a p+ doped back gate/body contact 160 are also implanted in the PBL 112.

A pre-metal dielectric (PMD) layer 164 is formed over the gate 132, the sidewall spacers 140, and the portions of the DNWELL 128, the drain 144, the SNW 148, the STI 152, the source 156, and the back gate/body contact 160 that are not covered by the gate structure. A dielectric layer (or multiple dielectric layers) 176 covers the PMD layer 164 and includes traces and other conductors connected to the contacts of the power transistor 100. For example, corresponding unreferenced vias connect: a conductor 180 to the back gate/body contact 160; a connector 182 to the source 156; a connector 184 to the gate 132; and a connector 186 to the drain 144.

The present disclosure introduces integrating a thermocouple with the power transistor 100 (and other transistors), wherein the thermocouple is constructed from the same material layers used in the power transistor 100. The thermocouple can be connected to circuitry (not shown in the figures) to sense temperature gradients resulting from operation of the power transistor 100, or an array of instances of the power transistor 100, whether such circuitry is on the power transistor chip or otherwise.

The thermocouple comprises an n-type thermopile (“n-thermopile”) and a p-type thermopile (“p-thermopile”). Each thermopile is a section of conductive material, such as doped crystalline or polycrystalline silicon or another semiconductor. The opposing ends of such a conductor, when placed in different temperatures, exhibit a voltage difference due to thermoelectric effects. The Seebeck coefficient is the relationship between the temperature differential and the resulting voltage difference sensed at the opposing ends of the thermopile. By combining two thermopiles of opposite Seebeck coefficient, where the thermopiles are connected electrically in series and generally arranged thermally in parallel, their Seebeck voltages constructively add and their electrical connections can be made at the same temperature node.

The p-thermopile and the n-thermopile are each electrically isolated from the power transistor and the semiconductor substrate while being sensitive to temperature differences within the power transistor IC apparatus resulting from operation of the power transistor. The p-thermopile comprises a p-type thermoelectric body (the thermoelectric portion) formed in a p-type one or more of the power transistor layers simultaneously with the formation of one or more p-type features of the power transistor, such as the PBL 112 or the back gate/body contact 160. The n-thermopile comprises an n-type thermoelectric body formed in an n-type one or more of the power transistor layers simultaneously with the formation of one or more n-type features of the power transistor, such as the NBL 108, the DEEPN 116, the n+ drain 144, the DNWELL 128, or the n+ source 156.

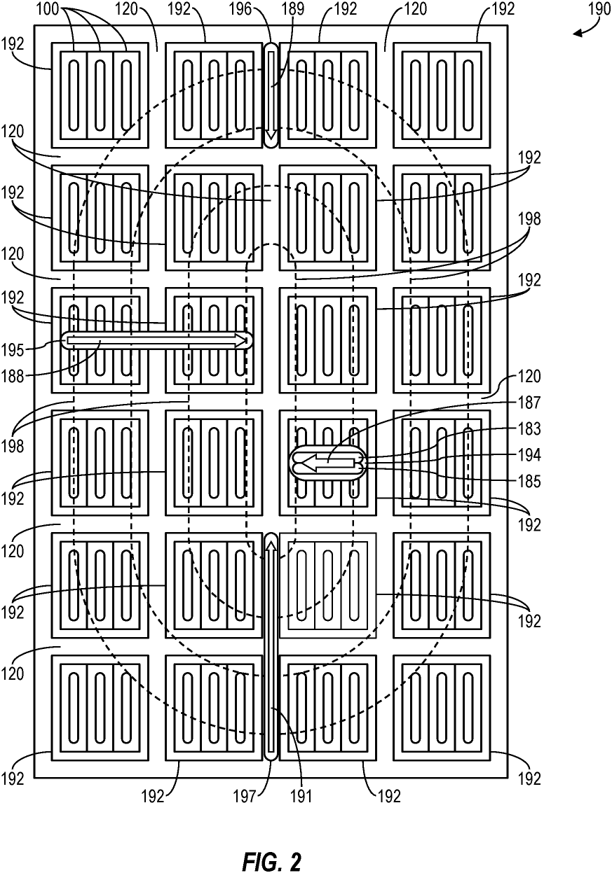

FIG. 2 is a plan view of an example implementation of a power transistor IC apparatus 190 comprising an array of multiple instances of the power transistor 100 shown in FIG. 1. The power transistors 100 are separated into banks 192 by the deep trenches 120. The power transistor IC apparatus 190 includes multiple instances of the above-described thermocouple, identified in FIG. 2 by reference numbers 194-197. The n-type and p-type thermoelectric bodies within each thermocouple are arranged, relative to one or more of the power transistors 100, so as to experience the same thermal gradient induced by operation of one or more of the power transistors 100.

For example, the example thermocouple 194 is arranged central to and spanning one transistor bank 192, wherein a n-type thermoelectric body 183 and a p-type thermoelectric body 185 of the thermocouple 194 are arranged, relative to that transistor bank 192, to sense the same thermal gradient therein, said thermal gradient being indicated in FIG. 2 by an arrow 187 pointing in the direction of increasing temperature. Another example thermocouple 195 is arranged central to and spanning multiple transistor banks 192 so that the n-type and p-type thermoelectric bodies (not shown) of the thermocouple 195 each similarly experience and sense a thermal gradient 188. Additional example thermocouples may be aligned with a deep trench 120 between neighboring transistor banks 192 (e.g., in an “isolation street” between nearest neighbor transistors 100 of adjacent banks 192), such as an example thermocouple 196 having a length of (or similar to) a side-dimension of one transistor bank 192, so that the n-type and p-type thermoelectric bodies (not shown) of the thermocouple 196 each similarly experience and sense a thermal gradient 189. Another thermocouple 197 has a greater length (e.g., spanning two or more transistor banks 192 within an isolation street), so that the n-type and p-type thermoelectric bodies (not shown) of the thermocouple 197 each similarly experience and sense a thermal gradient 191. Each thermocouple 194-197 is arranged perpendicular to isotherms 198 resulting from operation of the power transistors 100. The isotherms 198 lines of constant temperature that decreases in a radially outward direction from the center of the transistor array.

The thermocouples 194-197 are only schematically depicted in FIG. 2, in order to demonstrate possible locations of one or more thermocouples within a power transistor array. However, it should be understood that one or more such thermocouples may be formed over the transistors (as in FIG. 2), under the transistors, or alongside the transistors.

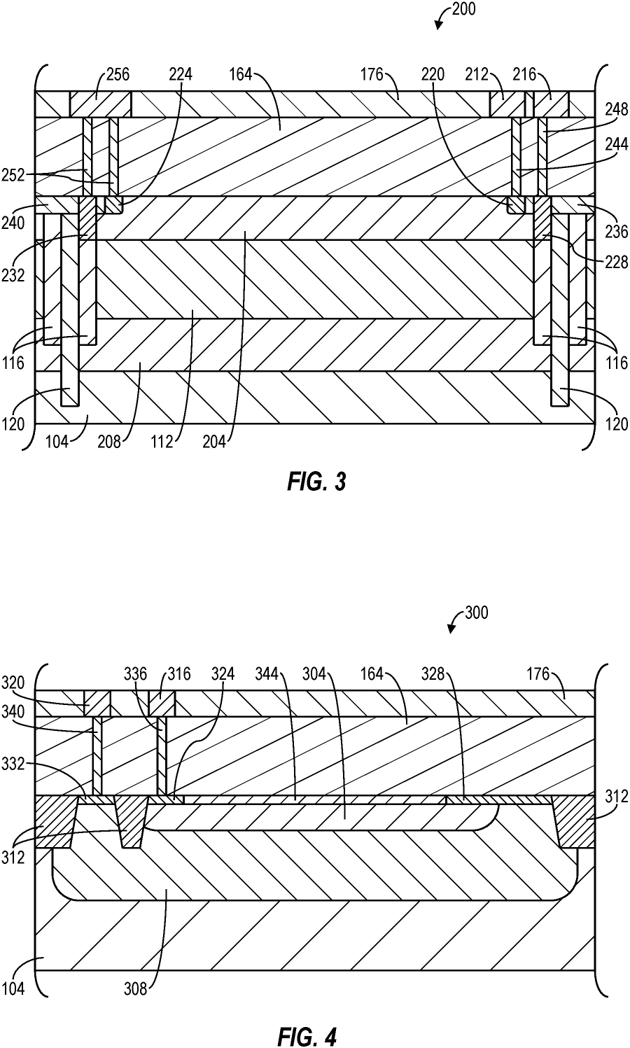

FIG. 3 is a schematic sectional view of a portion of an example implementation of a thermocouple 200 in an intermediate stage of manufacture according to one or more aspects of the present disclosure. The thermocouple 200 is an example implementation of the thermocouples 194-197 shown in FIG. 2. However, the thermocouple 200 is constructed simultaneously with, and from the same material layers of, a power transistor such as the power transistor 100 depicted in FIG. 1. Accordingly, the following description refers to FIGS. 1 and 3, collectively.

The thermocouple 200 is a trench-isolated, silicon-to-silicon thermocouple, meaning that the oppositely doped thermoelectric bodies are oppositely doped regions of crystalline silicon isolated from each other via opposing instances of the deep trench 120. For example, the thermocouple 200 includes a p-thermoelectric body 204 that is a p-type implanted region of crystalline silicon formed simultaneously with a shallow p-type well (SPW) of the power transistor 100 (not shown in FIG. 1). The thermocouple 200 also includes an n-thermoelectric body 208 that is an n-type implanted region of crystalline silicon formed simultaneously with the NBL 108 and/or other n-type features of the power transistor 100. The thermoelectric bodies 204, 208 are isolated by the opposing deep trenches 120.

The thermocouple 200 includes a positive terminal 212 and a negative terminal 216, each formed simultaneously with the conductors 180, 182, 184, 186, such as by deposition and subsequent planarization of aluminum, damascene copper, plated top copper, tungsten, a silicide (such as tungsten, vanadium, titanium, cobalt, nickel, or platinum), and/or other conductive materials. The p-type thermopile includes p-type ohmic connections electrically connected to opposing ends of the p-type thermoelectric body 204. In the example implementation depicted in FIG. 3, such connections are a first p+ doped region 220 implanted in one end of the p-type thermoelectric body 204 and a second p+ doped region 224 implanted in the other end of the p-type thermoelectric body 204, each formed simultaneously with a p-type source/drain region (PSD, not shown), the p+ back gate/body contact 160, and/or other p+ or other p-type features of the power transistor 100. The n-type thermopile similarly includes n-type ohmic connections electrically connected to opposing ends of the n-type thermoelectric body 208. In the example implementation depicted in FIG. 3, such connections are a first n-doped region 228, connected to one end of the n-type thermoelectric body 208 by one portion of the DEEPN 116, and a second n-doped region 232, connected to the other end of the n-type thermoelectric body 208 by another portion of the DEEPN 116.

The first p+ doped region 220 and the first n-doped region 228 are electrically isolated by an STI 236. The second p+ doped region 224 and the second n-doped region 232 are electrically isolated by an STI 240. Each STI 236, 240 are formed simultaneously with the STI 152 of the power transistor 100.

The first p+ doped region 220 is connected to the positive terminal 212 by a via 244 formed of tungsten or other conductive materials simultaneously with the unreferenced vias shown in FIG. 1. The first n-doped region 228 is similarly connected by a via 248 to the negative terminal 216. The second p+ doped region 224 and the second n-doped region 232 are connected together by similar vias 252 and a conductor 256 formed simultaneously with the terminals 212, 216.

The first p+ doped region 220 and the first n-doped region 228 forming the ohmic connections at one end of the respective p-thermoelectric body 204 and the n-thermoelectric body 208 are co-located. That is, such ohmic connections are set side by side or otherwise in close proximity (e.g., within five microns of each other, or within a distance from each other that is less than 30% of the largest dimension (e.g., along a longitudinal axis) of the thermoelectric bodies). The second p+ doped region 224 and the second n-doped region 232 forming the ohmic connections at the other end of the respective p-thermoelectric body 204 and the n-thermoelectric body 208 are similarly co-located. Accordingly, the p-type and n-type thermoelectric bodies 204, 208 each extend laterally between common first and second locations. Thus, the p-type and n-type thermoelectric bodies 204, 208 are arranged relative to each other and one or more instances of the power transistor 100 so as to experience the same thermal gradient induced by operation of the power transistor(s) 100, such as in one of the arrangements of the thermocouples 194-197 depicted in FIG. 2.

A trench-isolated, silicon-to-silicon thermocouple according to one or more aspects of the present disclosure is not limited to the example thermocouple 200 depicted in FIG. 3. For example, the p-type thermoelectric body may be formed simultaneously with at least one other p-type feature of the power transistor, such as at least one of p-type epitaxial layer, a PBL, an SPW, a PSD, a p-type reduced surface electric field region (PRSRF), a p-type deep well (DPWELL), and/or other p-type features. Similarly, the n-type thermoelectric body may be formed simultaneously with at least one other n-type feature of the power transistor, such as at least one of an NBL, an n-type deep trench, an SNW, an n-type source/drain region (NSD), an n-type drift region (NDRIFT), a DEEPN, and/or other n-type features.

FIG. 4 is a schematic sectional view of a portion of another example implementation of a thermocouple 300 in an intermediate stage of manufacture according to one or more aspects of the present disclosure. The thermocouple 300 is another example implementation of the thermocouples 194-197 shown in FIG. 2. However, the thermocouple 300 is constructed simultaneously with, and from the same material layers of, a power transistor such as the power transistor 100 depicted in FIG. 1. Accordingly, the following description refers to FIGS. 1 and 4, collectively.

The thermocouple 300 is an STI-isolated, silicon-to-silicon thermocouple, meaning that the oppositely doped thermoelectric bodies are oppositely doped regions of crystalline silicon isolated via one or more STI features. For example, the thermocouple 300 includes a p-thermopile having a p-thermoelectric body 304 that is a p+ implanted region of crystalline silicon formed simultaneously with a PSD, the p+ back gate/body contact 160, and/or other p+ or other p-type features of the power transistor 100. The thermocouple 300 also includes an n-thermopile having an n-thermoelectric body 308 that is an n-type implanted region of crystalline silicon formed simultaneously with the SNW 148 and/or other n-type features of the power transistor 100. The n-thermoelectric body 308 is implanted in the p-type semiconductor substrate 104, although the n-thermoelectric body 308 may instead be implanted in the PBL 112, a p-type epitaxial layer (p-epi, not shown in the figures), and/or other p-type features of the power transistor 100. The thermoelectric bodies 304, 308 are isolated by one or more STI features 312 formed simultaneously with the STI 152.

The thermocouple 300 includes a positive terminal 316 and a negative terminal 320, each formed simultaneously with the conductors 180, 182, 184, 186, such as by deposition and subsequent planarization of aluminum, damascene copper, plated top copper, tungsten, a silicide (such as tungsten, vanadium, titanium, cobalt, nickel, or platinum), and/or other conductive materials. The p-type thermopile includes p-type ohmic connections electrically connected to opposing ends of the p-type thermoelectric body 304. In the example implementation depicted in FIG. 4, such connections are a first silicide contact 324 deposited on one end of the p-type thermoelectric body 304 and a second silicide contact 328 deposited on the other end of the p-type thermoelectric body 304. The n-type thermopile similarly includes n-type ohmic connections electrically connected to opposing ends of the n-type thermoelectric body 308. In the example implementation depicted in FIG. 4, such connections are a third silicide contact 332 and the second silicide contact 328, such that the second silicide contact 328 connects one end of the p-type thermoelectric body 304 to the co-located end of the n-thermoelectric body 308. At the opposing co-located ends of the thermoelectric bodies 304, 308, a via 336 connects the first silicide contact 324 to the positive terminal 316 and another via 340 connects the third silicide contact 332 to the negative terminal 320. As with the thermocouple 200 shown in FIG. 3, the thermoelectric bodies 304, 308 are arranged relative to each other and one or more instances of the power transistor 100 so as to experience the same thermal gradient induced by operation of the power transistor(s) 100, such as in one of the arrangements of the thermocouples 194-197 depicted in FIG. 2.

The vias 336, 340 are formed simultaneously with the unreferenced vias of the power transistor 100 shown in FIG. 1, whereas the silicide contacts 324, 328, 332 are formed simultaneously with silicide features of the power transistor 100 (not shown). The thermocouple 300 also includes a silicide blocking layer 344 deposited over a substantial portion (e.g., at least 90%) of the surface area of the p-thermoelectric body 304 in order to prevent the silicide from disrupting the intended thermoelectric function of the p-thermoelectric body 304.

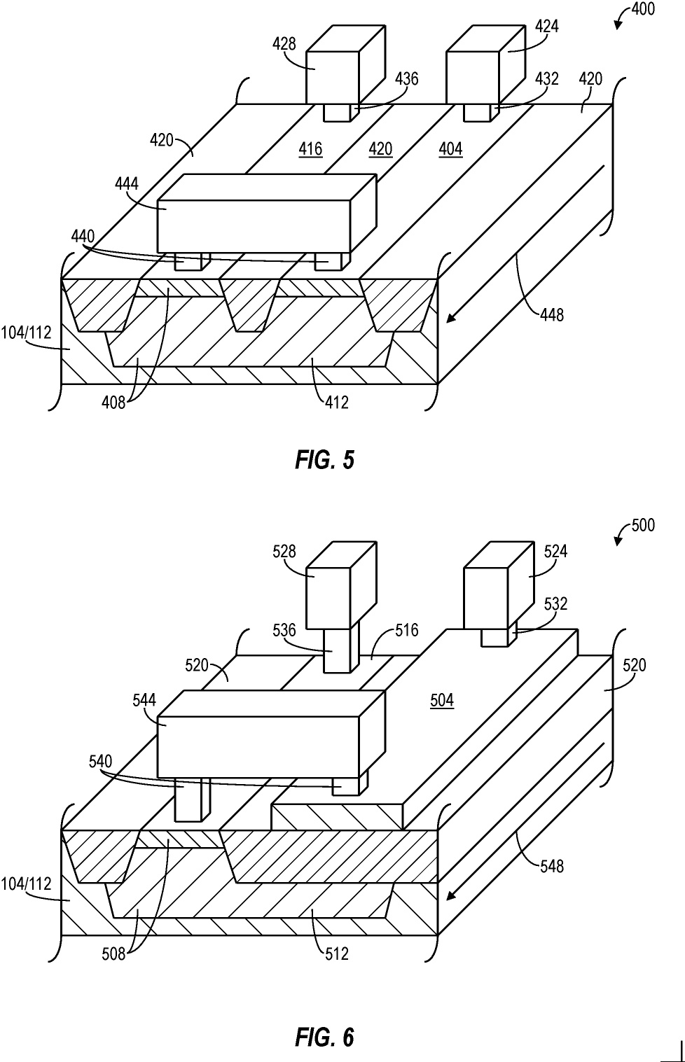

FIG. 5 is a schematic sectional and perspective view of a portion of another example implementation of a thermocouple 400 in an intermediate stage of manufacture according to one or more aspects of the present disclosure. The thermocouple 400 is another example implementation of the thermocouples 194-197 shown in FIG. 2. However, the thermocouple 400 is constructed simultaneously with, and from the same material layers of, a power transistor such as the power transistor 100 depicted in FIG. 1. Accordingly, the following description refers to FIGS. 1 and 5, collectively.

The thermocouple 400 is an STI-isolated, silicon thermocouple, meaning that the oppositely doped thermoelectric bodies are oppositely doped portions of the same region of crystalline silicon, wherein the oppositely doped portions are isolated via one or more STI features. For example, the thermocouple 400 includes a p-thermoelectric body 404 that is a p-type implanted region of crystalline silicon formed simultaneously with a PSD, the p+ back gate/body contact 160, and/or other p+ or other p-type features of the power transistor 100. The thermocouple 400 also includes an n-thermoelectric body 408 that includes two n-type implanted regions 412, 416 of crystalline silicon. The n-type region 412 is formed simultaneously with the SNW 148 and/or other n-type features of the power transistor 100, whereas the n-type region 416 is formed simultaneously with the n+ drain 144, the n+ source 156, and/or other n-type features of the power transistor 100. The n-thermoelectric body 408 is implanted in the p-type semiconductor substrate 104, the PBL 112, and/or other p-type features of the power transistor 100. The thermoelectric bodies 404, 408 are isolated by STI features 420 formed simultaneously with the STI 152.

The thermocouple 400 includes a positive terminal 424 and a negative terminal 428, each formed simultaneously with the conductors 180, 182, 184, 186, such as by deposition and subsequent planarization of aluminum, damascene copper, plated top copper, tungsten, a silicide (such as tungsten, vanadium, titanium, cobalt, nickel, or platinum), and/or other conductive materials. One or more vias, traces, silicide region, and/or other conductive features 432 connect one end of the p-thermoelectric body 404 to the positive terminal 424, one or more such conductive features 436 connect the co-located end of the n-thermoelectric body 408 to the negative terminal 428, and one or more such conductive features 440 connect each of the other co-located ends of the thermoelectric bodies 404, 408 to a conductor 444 so as to connect said other co-located ends. The conductive features 432, 436, 440, 444 are formed simultaneously with interconnect features of the power transistor 100.

As with the thermocouples 200, 300 shown in FIGS. 3 and 4, the thermoelectric bodies 404, 408 are arranged relative to each other and one or more instances of the power transistor 100 so as to experience the same thermal gradient induced by operation of the power transistor(s) 100, such as in one of the arrangements of the thermocouples 194-197 depicted in FIG. 2. The thermal gradient is depicted in FIG. 5 by arrow 448, indicating the direction of increasing temperature. As also depicted in FIG. 5, the thermocouple terminals 424, 428 are co-located at the cooler end of the thermocouple 400, so that the voltage of the thermocouple 400 can advantageously be detected at the cooler temperature. Co-locating the terminals 424, 428 may aid in avoiding thermoelectric potential differences in the metal connections, because although the Seebeck coefficient of such metal components is much smaller than for semiconductor materials, the metal connections may nonetheless cause errors. Additionally, for implementations that utilize an integrated thermocouple to monitor and/or manage thermal self-heating and/or runaway situations (and other implementations within the scope of the present disclosure), locating the terminals 424, 428 at the cooler ends of the thermoelectric bodies 404, 408 may aid in maintaining the accuracy and/or other aspects of the readout electronics (not shown) utilized to sense voltage at the terminals 424, 428, because such readout electronics may be less accurate at higher temperatures and/or the temperature at the warmer ends of the thermoelectric bodies 404, 408 may vary significantly more than at the cooler ends.

An STI-isolated, silicon thermocouple according to one or more aspects of the present disclosure is not limited to the example thermocouple 400 shown in FIG. 5. For example, one (or each) of the p-type and n-type thermoelectric bodies may be formed simultaneously with two other respective p-type or n-type features of the power transistor that are not formed simultaneously. An example of such implementations includes a p-type thermoelectric body formed simultaneously with both an implanted PSD and a p-type moat region (PMOAT) subsequently implanted around the PSD, or a p-type thermoelectric body formed simultaneously with both an implanted DPWELL and a PSD subsequently implanted in the DPWELL. However, other implementations are also within the scope of the present disclosure.

FIG. 6 is a schematic sectional and perspective view of a portion of another example implementation of a thermocouple 500 in an intermediate stage of manufacture according to one or more aspects of the present disclosure. The thermocouple 500 is another example implementation of the thermocouples 194-197 shown in FIG. 2. However, the thermocouple 500 is constructed simultaneously with, and from the same material layers of, a power transistor such as the power transistor 100 depicted in FIG. 1. Accordingly, the following description refers to FIGS. 1 and 6, collectively.

The thermocouple 500 is an STI-isolated, silicon-to-polysilicon thermocouple, wherein the oppositely doped thermoelectric bodies include a crystalline silicon region doped opposite to a polysilicon region that is isolated from the crystalline silicon region by one or more STI features. For example, the thermocouple 500 includes a p-thermoelectric body 504 that is a p-type region of polysilicon implanted simultaneously with a PSD, a p-type deep well (DPWELL), the p+ back gate/body contact 160, and/or other p+ or other p-type features of the power transistor 100. The thermocouple 500 also includes an n-thermoelectric body 508 that includes two n-type implanted regions 512, 516 of crystalline silicon. The n-type region 512 is formed simultaneously with the SNW 148 and/or other n-type features of the power transistor 100, whereas the n-type region 516 is formed simultaneously with the n+ drain 144, the n+ source 156, and/or other n-type features of the power transistor 100. The n-thermoelectric body 508 is implanted in the p-type semiconductor substrate 104, the PBL 112, and/or other p-type features of the power transistor 100. The thermoelectric bodies 504, 508 are isolated by STI features 520 formed simultaneously with the STI 152.

The thermocouple 500 includes a positive terminal 524 and a negative terminal 528, each formed simultaneously with the conductors 180, 182, 184, 186. One or more vias, traces, silicide region, and/or other conductive features 532 connect one end of the p-thermoelectric body 504 to the positive terminal 524, one or more such conductive features 536 connect the co-located end of the n-thermoelectric body 508 to the negative terminal 528, and one or more such conductive features 540 connect each of the other co-located ends of the thermoelectric bodies 504, 508 to a conductor 544 so as to connect said other co-located ends. The conductive features 532, 536, 540, 544 are formed simultaneously with other interconnect features of the power transistor 100.

As with the thermocouples 200, 300, 400 shown in FIGS. 3-5, the thermoelectric bodies 504, 508 are arranged relative to each other and one or more instances of the power transistor 100 so as to experience the same thermal gradient induced by operation of the power transistor(s) 100, such as in one of the arrangements of the thermocouples 194-197 depicted in FIG. 2. The thermal gradient is depicted in FIG. 6 by arrow 548, indicating the direction of increasing temperature. As also depicted in FIG. 6, the thermocouple terminals 524, 528 are located at the cooler end of the thermocouple 500, so that the voltage of the thermocouple 500 can advantageously be detected at the cooler temperature.

An STI-isolated, silicon-to-polysilicon thermocouple according to one or more aspects of the present disclosure is not limited to the example thermocouple 500 shown in FIG. 6. For example, one (or each) of the p-type and n-type thermoelectric bodies may be formed simultaneously with two other respective p-type or n-type features of the power transistor that are not formed simultaneously. An example of such implementations includes a p-type thermoelectric body formed simultaneously with both an implanted DPWELL and a PSD subsequently implanted in the DPWELL. However, other implementations are also within the scope of the present disclosure.

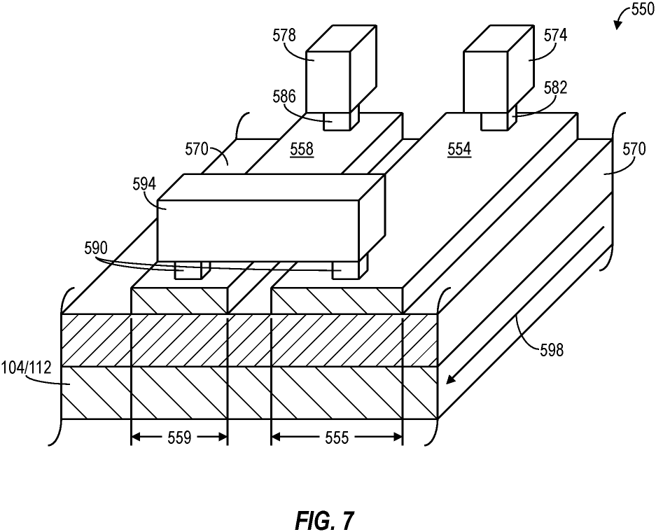

FIG. 7 is a schematic sectional and perspective view of a portion of another example implementation of a thermocouple 550 in an intermediate stage of manufacture according to one or more aspects of the present disclosure. The thermocouple 550 is another example implementation of the thermocouples 194-197 shown in FIG. 2. However, the thermocouple 550 is constructed simultaneously with, and from the same material layers of, a power transistor such as the power transistor 100 depicted in FIG. 1. Accordingly, the following description refers to FIGS. 1 and 7, collectively.

The thermocouple 550 is an STI-isolated, polysilicon-to-polysilicon thermocouple, wherein the oppositely doped thermoelectric bodies include oppositely doped polysilicon regions isolated by one or more STI features. For example, the thermocouple 550 includes a p-thermoelectric body 554 that is a p-type region of polysilicon implanted simultaneously with one or more of a PSD, a p-type deep well (DPWELL), the p+ back gate/body contact 160, and/or other p+ or other p-type features of the power transistor 100. The thermocouple 550 also includes an n-thermoelectric body 558 that is an n-type region of polysilicon implanted simultaneously with one or more of the SNW 148, the n+ drain 144, the n+ source 156, and/or other n-type features of the power transistor 100. The thermoelectric bodies 554, 558 are isolated by one or more STI features 570 formed simultaneously with the STI 152.

The thermocouple 550 includes a positive terminal 574 and a negative terminal 578, each formed simultaneously with the conductors 180, 182, 184, 186. One or more vias, traces, silicide regions, and/or other conductive features 582 connect one end of the p-thermoelectric body 554 to the positive terminal 574, one or more such conductive features 586 connect the co-located end of the n-thermoelectric body 558 to the negative terminal 578, and one or more such conductive features 590 connect each of the other co-located ends of the thermoelectric bodies 554, 558 to a conductor 594 so as to connect said other co-located ends. The conductive features 582, 586, 590, 594 are formed simultaneously with other interconnect features of the power transistor 100.

As with the thermocouples 200, 300, 400, 500 shown in FIGS. 3-6, the thermoelectric bodies 554, 558 are arranged relative to each other and one or more instances of the power transistor 100 so as to experience the same thermal gradient induced by operation of the power transistor(s) 100, such as in one of the arrangements of the thermocouples 194-197 depicted in FIG. 2. The thermal gradient is depicted in FIG. 7 by arrow 598, indicating the direction of increasing temperature. As also depicted in FIG. 7, the thermocouple terminals 574, 578 are located at the cooler end of the thermocouple 550, so that the voltage of the thermocouple 550 can advantageously be detected at the cooler temperature, as described above.

FIG. 7 also depicts that, if the doping concentrations of the p-thermoelectric body 554 and the n-thermoelectric body 558 are the same, the n-thermoelectric body 558 can have a smaller width 559 that the width 555 of the p-thermoelectric body 554 because the mobility of electrons in polysilicon is higher than the mobility of holes. However, it is possible that the bodies 554, 558 have unequal doping concentrations. Thus, another way to specify the widths 555, 559 is by the square root of the ratio of sheet resistances. For example, if the n-type thermoelectric body 558 has a sheet resistance of 10 ohm-centimeter (ohm-cm), and the p-type thermoelectric body 554 has a sheet resistance of 20 ohm-cm, then the width 555 of the p-type thermoelectric body 554 should be about 1.4 (the square root of 2) times more than the width 559 of the n-type thermoelectric body 558, assuming that (as depicted in the example implementation 550 of FIG. 7) the bodies 554, 558 are equal in length.

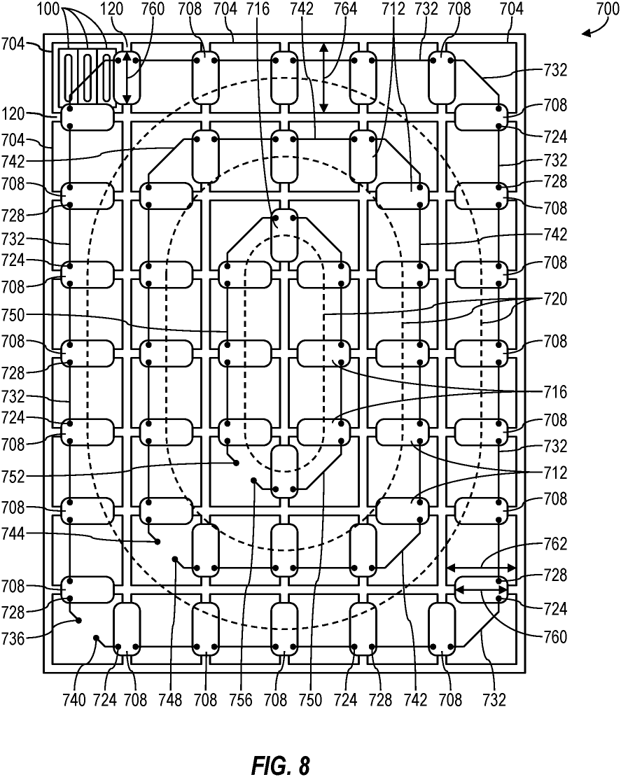

FIG. 8 is a plan view of another example implementation of a power transistor IC apparatus 700 comprising an array of multiple instances of the power transistor 100 shown in FIG. 1. The power transistors 100 are separated into banks 704 by the deep trenches 120. The array of transistor banks 704 are laterally disposed in six columns and eight rows. However, other implementations within the scope of the present disclosure may include any number of rows and columns of transistor banks 704 (or an array of the power transistors 100 not separated into transistor banks), wherein at least one of the numbers of rows and columns is greater than one. For the purposes of simplicity and clarity of view, FIG. 8 only depicts the power transistors 100 in one of the transistor banks 704, it being understood that each transistor bank includes a plurality of the power transistors 100 and/or other power transistors also within the scope of the present disclosure. For similar purposes, only some of the deep trenches 120, the transistor banks 704, and other multiple-instance features are labelled with reference numbers in FIG. 8.

The power transistor IC apparatus 700 also includes an outer array of thermocouples 708, an intermediate array of thermocouples 712, and an inner array of thermocouples 716. The inner array of thermocouples 716 may be viewed as an interior portion of the combined array of thermocouples 708, 712, 716, and the outer array of thermocouples 708 may be viewed as a peripheral portion of the combined array. Each thermocouple 708, 712, 716 is disposed between two neighboring transistor banks 704, such as in the manner of the thermocouple 196 shown in FIG. 2. Each array of thermocouples 708, 712, 716 is laterally disposed in a pattern based on isotherms 720 of the array transistor banks 704. The pattern of each array of thermocouples 708, 712, 716 may be cosymmetric with the isotherms 720. For example, major and minor lateral axes of each array of thermocouples 708, 712, 716 and each isotherm 720 may each be colinear with respective major and minor axes of the array of transistor banks 704. Each thermocouple 708, 712, 716 has a positive terminal 724 and a negative terminal 728 at the cooler end thereof.

The thermocouples 708, 712, 716 of each array are electrically connected in series to increase thermoelectric gain between temperature difference and output voltage. For example, traces, vias, and/or other conductors 732 connect the positive terminal 724 of each outer thermocouple 708 with the negative terminal 728 of the neighboring thermocouple 708. However, the positive terminal 724 of one of the outer thermocouples 708 is connected to a positive series contact 736, and the negative terminal 728 of the neighboring outer thermocouple 708 is connected to a negative series contact 740, such that the positive and negative series contacts 736, 740 reflect the combined voltages of each of the outer thermocouples 708. The intermediate array of thermocouples 712 are similarly connected by conductors 742 in series between positive and negative series contacts 744, 748, and the inner array of thermocouples 716 are similarly connected by conductors 750 in series between positive and negative series contacts 752, 756.

Each thermocouple 708, 712, 716 may be an instance of the thermocouple 200 shown in FIG. 3 and/or otherwise within the scope of the present disclosure. The thermocouples 708, 712, 716 of each array are connected electrically in series. Moreover, because the thermocouples 708, 712, 716 of each array are laterally disposed in a pattern based on the isotherms 720, the thermocouples 708, 712, 716 of each array are essentially arranged thermally in parallel. In other words, each (or most) of the thermocouples 708, 712, 716 of each array are span approximately the same first and second temperatures (as given by the isotherms 720 of the power transistor array) so that they are thermally in parallel. The thermocouples 708, 712, 716 of each array are connected electrically in series, so that their thermoelectric voltages add, which increases the thermoelectric gain between temperature difference and output voltage.

In the example implementation depicted in FIG. 7, the power transistor IC apparatus 700 includes the same number (48) of transistor banks 704 and thermocouples 708, 712, 716 (collectively), such that the ratio of transistor banks to thermocouples is 1:1. However, ratios other than 1: 1 are also within the scope of the present disclosure. For example, each thermocouple 708, 712, 716 shown in FIG. 7 has a length 760 not extending beyond the corresponding width 762 or length 764 of the adjacent transistor banks 704, such as in the manner of the thermocouple 196 shown in FIG. 2. However, in other implementations within the scope of the present disclosure, one or more of the thermocouples 708, 712, 716 may extend past one or transistor blocks 704, such as in the manner of the thermocouple 197 shown in FIG. 2, such that fewer thermocouples are needed to sense temperatures throughout the power transistor IC apparatus. Thus, the ratio of transistor banks to thermocouples may be greater than 1: 1.

The power transistor IC apparatus according to one or more aspects introduced herein each include an integrated thermocouple that comprises a p-thermopile and/or an n-thermopile and that senses temperature differences which directly relate heat flow along the thermocouple. In contrast, the conventional practice of using a thermal diode senses absolute temperature. By directly sensing temperature gradients, the thermopile-formed thermocouple is a more accurate way to sense power dissipation in a power transistor array relative to a thermal diode, because the conventional thermal diodes sense absolute temperature which are affected by background temperature variations from the ambient environment, a circuit board comprising the power transistor IC, and/or other areas of the IC. An array of the thermopile-formed thermocouples can also sense local temperature differences to detect the formation of a hot spot, which is a direct indication of thermal runaway.

The thermopile-formed thermocouple, as a sensor, also has the advantage of producing a differential voltage signal, which is simple to sense using a differential amplifier and/or other circuitry. In contrast, thermal diodes require more complex circuitry for temperature readout. For example, when a thermal diode is used in a delta-VBE (base-emitter voltage) configuration as in a bandgap reference, current biasing circuitry is required for configuration, which also dissipates power. However, the thermopiles are self-biasing through majority carrier diffusion so that, in effect, the thermopiles power their own operation by harvesting thermal energy from the crystal lattice.

In view of the entirety of the present disclosure, including the figures and the claims, a person having ordinary skill in the art will readily recognize that the present disclosure introduces an IC apparatus, comprising: (A) a power transistor constructed in a plurality of layers formed over a semiconductor substrate; and (B) a thermocouple comprising a p-thermopile and an n-thermopile that are each electrically isolated from the power transistor and the semiconductor substrate while being sensitive to temperature differences within the IC resulting from operation of the power transistor, wherein: (1) the p-thermopile comprises a p-type thermoelectric body formed in a p-type one or more of the plurality of layers; and (2) the n-thermopile comprises an n-type thermoelectric body formed in an n-type one or more of the plurality of layers.

The p-type and n-type thermoelectric bodies may each extend laterally between common first and second locations.

The p-type and n-type thermoelectric bodies may be arranged, relative to each other and to the power transistor, to experience the same thermal gradient induced by operation of the power transistor.

The thermocouple may comprise a positive terminal and a negative terminal, the p-type thermopile may comprise first and second p-type ohmic connections electrically connected to opposing ends of the p-type thermoelectric body, the n-type thermopile may comprise first and second n-type ohmic connections electrically connected to opposing ends of the n-type thermoelectric body, the first p-type and n-type ohmic connections may be co-located and respectively connected to the positive and negative terminals, and the second p-type and n-type ohmic connections may be co-located and electrically connected. The temperature differences within the IC resulting from the power transistor operation, and to which the thermocouple is sensitive, may be thermal gradients that increase along a direction from the first p-type and n-type ohmic connections to the second p-type and n-type ohmic connections.

In an example implementation, the p-type and n-type thermoelectric bodies are electrically isolated by at least one trench filled with a dielectric material and extending through ones of the layers to the semiconductor substrate, the p-type thermoelectric body is a p-doped silicon region formed simultaneously, e.g., using a same process step or steps, with at least one other p-type feature of the power transistor (e.g., at least one of a p-type epitaxial layer, a p-type buried layer, a p-type shallow well, a p-type source/drain region, a p-type reduced surface electric field region, and a p-type deep well), and the n-type thermoelectric body is an n-doped silicon region formed simultaneously, e.g., using a same process step or steps, with at least one other n-type feature of the power transistor (e.g., at least one of an n-type buried layer, an n-type deep trench, an n-type shallow well, an n-type source/drain region, an n-type drift region, and an n-type deep well).

In another example implementation, the p-type and n-type thermoelectric bodies are junction-isolated portions of a silicon region, the p-type thermoelectric body is a p-doped portion of the silicon region formed simultaneously with at least one other p-type feature of the power transistor (e.g., at least one of a p-type epitaxial layer, a p-type buried layer; a p-type shallow well, a p-type source/drain region, a p-type reduced surface electric field region, and a p-type deep well), and the n-type thermoelectric body is an n-doped portion of the silicon region formed simultaneously with at least one other n-type feature of the power transistor; (e.g., at least one of an n-type buried layer, an n-type deep trench, an n-type shallow well, an n-type source/drain region, an n-type reduced surface electric field region, an n-type drift region, and an n-type deep well).

In another example implementation, the p-type and n-type thermoelectric bodies are electrically isolated by at least one or more shallow trench isolation features, the p-type thermoelectric body is a p-doped silicon region formed simultaneously with at least one other p-type feature of the power transistor (e.g., at least one of a p-type source/drain region, a p-type moat, a p-type deep well, and a p-type source/drain region), and the n-type thermoelectric body is an n-doped silicon region formed simultaneously with at least one other n-type feature of the power transistor (e.g., at least one of an n-type shallow well, an n-type drift region, and an n-type deep well).

In another example implementation, the p-type and n-type thermoelectric bodies are electrically isolated by at least one or more shallow trench isolation features, the p-type thermoelectric body is a p-doped polysilicon region formed simultaneously with at least one other p-type feature of the power transistor (e.g., at least one of a p-type source/drain region and a p-type deep well), and the n-type thermoelectric body is an n-doped silicon region formed simultaneously with at least one other n-type feature of the power transistor (e.g., at least one of an n-type shallow well, an n-type drift region, and an n-type deep well).

The power transistor may be one of a plurality of power transistors constructed in the plurality of layers and laterally disposed as an array having a first number of rows and a second number of columns, wherein at least one of the first and second numbers is greater than one, and the thermocouple may be one of a plurality of thermocouples laterally disposed in a pattern based on isotherms of the array. The plurality of thermocouples may be electrically connected in series.

The IC apparatus may comprise a power transistor array comprising a plurality of instances of the power transistor, the IC apparatus may comprise a plurality of thermocouple arrays each comprising a plurality of instances of the thermocouple connected electrically in series, and the thermocouples of each thermocouple array may be laterally disposed in a pattern based on isotherms of the power transistor array.

The present disclosure also introduces a method of manufacturing an IC apparatus comprising a power transistor. The method comprises, simultaneously with constructing the power transistor in a plurality of layers formed over a semiconductor substrate, forming a thermocouple that is electrically isolated from the power transistor and the semiconductor substrate while being sensitive to temperature differences within the IC resulting from operation of the power transistor, wherein: forming the thermocouple comprises forming a p-thermopile and an n-thermopile; forming the p-thermopile comprises forming a p-type thermoelectric body in a p-type one or more of the plurality of layers; and forming the n-thermopile comprises forming an n-type thermoelectric body in an n-type one or more of the plurality of layers.

Forming the thermocouple may comprise forming a positive terminal and a negative terminal in one or more of the plurality of layers, forming the p-type thermopile may comprise forming first and second p-type ohmic connections in one or more of the plurality of layers and electrically connected to opposing ends of the p-type thermoelectric body, forming the n-type thermopile may comprise forming first and second n-type ohmic connections in one or more of the plurality of layers and electrically connected to opposing ends of the n-type thermoelectric body, the first p-type and n-type ohmic connections may be co-located and respectively connected to the positive and negative terminals, and the second p-type and n-type ohmic connections may be co-located and electrically connected.

In an example implementation, the p-type and n-type thermoelectric bodies are electrically isolated by at least one trench filled with a dielectric material and extending through ones of the layers to the semiconductor substrate, forming the p-type thermoelectric body comprises forming a p-doped silicon region simultaneously with forming at least one other p-type feature of the power transistor (e.g., at least one of a p-type epitaxial layer, a p-type buried layer, a p-type shallow well, a p-type source/drain region, a p-type reduced surface electric field region, and a p-type deep well), and forming the n-type thermoelectric body comprises forming an n-doped silicon region simultaneously with forming at least one other n-type feature of the power transistor (e.g., at least one of an n-type buried layer, an n-type deep trench, an n-type shallow well, an n-type source/drain region, an n-type drift region, and an n-type deep well).

In another example implementation, the p-type and n-type thermoelectric bodies are junction-isolated portions of a silicon region, forming the p-type thermoelectric body comprises forming a p-doped portion of the silicon region simultaneously with forming at least one other p-type feature of the power transistor (e.g., at least one of a p-type epitaxial layer, a p-type buried layer; a p-type shallow well, a p-type source/drain region, a p-type reduced surface electric field region, and a p-type deep well), and forming the n-type thermoelectric body comprises forming an n-doped portion of the silicon region simultaneously with forming at least one other n-type feature of the power transistor (e.g., at least one of an n-type buried layer, an n-type deep trench, an n-type shallow well, an n-type source/drain region, an n-type reduced surface electric field region, an n-type drift region, and an n-type deep well).

In another example implementation, the p-type and n-type thermoelectric bodies are electrically isolated by at least one or more shallow trench isolation features, forming the p-type thermoelectric body comprises forming a p-doped silicon region simultaneously with forming at least one other p-type feature of the power transistor (e.g., at least one of a p-type source/drain region, a p-type moat, a p-type deep well, and a p-type source/drain region), and forming the n-type thermoelectric body comprises forming an n-doped silicon region simultaneously with forming at least one other n-type feature of the power transistor (e.g., at least one of an n-type shallow well, an n-type drift region, and an n-type deep well).

In another example implementation, the p-type and n-type thermoelectric bodies are electrically isolated by at least one or more shallow trench isolation features, forming the p-type thermoelectric body comprises forming a p-doped polysilicon region simultaneously with forming at least one other p-type feature of the power transistor (e.g., at least one of a p-type source/drain region and a p-type deep well), and forming the n-type thermoelectric body comprises forming an n-doped silicon region simultaneously with forming at least one other n-type feature of the power transistor (e.g., at least one of an n-type shallow well, an n-type drift region, and an n-type deep well).

Forming the power transistor may comprise forming in the plurality of layers a plurality of instances of the power transistor laterally disposed as an array. In such implementations, among others within the scope of the present disclosure, forming the thermocouple may comprise forming in the plurality of layers a plurality of instances of the thermocouple laterally disposed in a pattern based on isotherms of the array.

Forming the power transistor may comprise forming in the plurality of layers a power transistor array comprising a plurality of instances of the power transistor, forming the thermocouple may comprise forming in the plurality of layers and simultaneously with forming the power transistor array a plurality of thermocouple arrays each comprising a plurality of instances of the thermocouple connected electrically in series, and the thermocouples of each thermocouple array may be laterally disposed in a pattern based on isotherms of the power transistor array.

The present disclosure also introduces an IC comprising: a transistor array including a plurality of transistors on or over a semiconductor substrate, wherein each transistor is electrically isolated from a neighboring transistor by an isolation structure, and wherein a perimeter of the transistor array defined by outermost ones of the transistors; and a plurality of thermocouples in or over the semiconductor substrate, wherein the thermocouples each have one or more semiconductor thermopiles formed in or over the semiconductor substrate and located within the perimeter of the transistor array.

The thermocouples may each be located within a perimeter of a corresponding one of the transistors.

The thermocouples may each be located in an isolation street between nearest neighbor transistors.

The transistors may be power transistors.

The thermocouples may each be junction isolated from the transistors.

The thermocouples may each be isolated from the transistors by a corresponding deep trench isolation structure.

The thermocouples may each include an n-type thermopile and a p-type thermopile electrically connected in series with the n-type thermopile.

The present disclosure also introduces an integrated circuit, comprising: a transistor formed in or over a semiconductor substrate and having a plurality of layers including at least one p-type layer and at least one n-type layer; and a thermocouple comprising a p-thermopile and an n-thermopile that are each electrically isolated from the transistor and located adjacent the transistor, wherein the p-thermopile comprises a p-type thermoelectric body formed in a p-type one or more of the plurality of layers, and wherein the n-thermopile comprises an n-type thermoelectric body formed in an n-type one or more of the plurality of layers.

The p-type and n-type thermoelectric bodies may each extend laterally between common first and second locations.

The p-type and n-type thermoelectric bodies may be arranged, relative to each other and to the transistor, to experience a same thermal gradient induced by operation of the transistor.

The thermocouple may comprise a positive terminal and a negative terminal, the p-type thermopile may comprise first and second p-type ohmic connections electrically connected to opposing ends of the p-type thermoelectric body, the n-type thermopile may comprise first and second n-type ohmic connections electrically connected to opposing ends of the n-type thermoelectric body, the first p-type and n-type ohmic connections may be co-located and respectively connected to the positive and negative terminals, and the second p-type and n-type ohmic connections may be co-located and electrically connected. The temperature differences within the integrated circuit resulting from the transistor operation, and to which the thermocouple is sensitive, may be thermal gradients that increase along a direction from the first p-type and n-type ohmic connections to the second p-type and n-type ohmic connections.

The p-type and n-type thermoelectric bodies may be electrically isolated by at least one trench filled with a dielectric material and extending through ones of the layers to the semiconductor substrate, the p-type thermoelectric body may be a p-doped silicon region formed simultaneously with at least one other p-type feature of the transistor (such as at least one of a p-type epitaxial layer, a p-type buried layer, a p-type shallow well, a p-type source/drain region, a p-type reduced surface electric field region, and a p-type deep well), and the n-type thermoelectric body may be an n-doped silicon region formed simultaneously with at least one other n-type feature of the transistor (such as at least one of an n-type buried layer, an n-type deep trench, an n-type shallow well, an n-type source/drain region, an n-type drift region, and an n-type deep well).

The p-type and n-type thermoelectric bodies may be junction-isolated portions of a silicon region, the p-type thermoelectric body may be a p-doped portion of the silicon region formed simultaneously with at least one other p-type feature of the transistor (such as at least one of a p-type epitaxial layer, a p-type buried layer, a p-type shallow well, a p-type source/drain region, a p-type reduced surface electric field region, and a p-type deep well), and the n-type thermoelectric body may be an n-doped portion of the silicon region formed simultaneously with at least one other n-type feature of the transistor (such as at least one of an n-type buried layer, an n-type deep trench, an n-type shallow well, an n-type source/drain region, an n-type reduced surface electric field region, an n-type drift region, and an n-type deep well).

The present disclosure also introduces a method of manufacturing an IC, comprising: forming an array of power transistors in or over a semiconductor substrate; forming a plurality of thermocouples within the array, wherein each thermocouple is electrically isolated from the power transistors and the semiconductor substrate and from others of the thermocouples; and configuring the thermocouples to provide an electrical signal responsive to heat flow from an interior portion of the array to a peripheral portion of the array.

Forming each thermocouple may comprise forming a p-thermopile and an n-thermopile, forming the p-thermopile may comprise forming a p-type thermoelectric body using one or more process steps used to form a p-type feature of the power transistors, and forming the n-thermopile may comprise forming an n-type thermoelectric body using one or more process steps used to form an n-type feature of the power transistors.

Forming each thermocouple may comprise forming a p-thermopile adjacent an n-thermopile, and the method may further comprise: electrically connecting co-located first ends of the p-thermocouple and the n-thermocouple of each thermocouple; electrically connecting a negative terminal of a first thermocouple to a positive terminal of a first nearest-neighbor thermocouple; and electrically connecting a positive terminal of the first thermocouple to a negative terminal of a second nearest-neighbor thermocouple. The co-located first ends may be located between a central portion of the array and the positive and negative terminals.

The method may further comprise electrically isolating each thermocouple from the array of transistors with a deep-trench isolation structure.

The thermocouples may be located between nearest-neighbor power transistors.

The foregoing outlines features of several embodiments so that a person having ordinary skill in the art may better understand the aspects of the present disclosure. A person having ordinary skill in the art will appreciate that they may readily use the present disclosure as a basis for designing or modifying other processes and structures for carrying out the same functions and/or achieving the same benefits of the embodiments introduced herein. A person having ordinary skill in the art will also realize that such equivalent constructions do not depart from the scope of the present disclosure, and that they may make various changes, substitutions and alterations herein without departing from the scope of the present disclosure.

The Abstract at the end of this disclosure is provided to comply with 37 C.F.R. §1.72(b) to permit the reader to quickly ascertain the nature of the technical disclosure. It is submitted with the understanding that it will not be used to interpret or limit the scope or meaning of the claims.

What is claimed is:

1. An integrated circuit, comprising:
a transistor array including a plurality of transistors on or over a semiconductor substrate, wherein each transistor is electrically isolated from a neighboring transistor by an isolation structure, and wherein a perimeter of the transistor array is defined by outermost ones of the transistors; and
a plurality of thermocouples in or over the semiconductor substrate, the thermocouples each having one or more semiconductor thermopiles formed in or over the semiconductor substrate and located within the perimeter of the transistor array.

2. The integrated circuit of claim 1 wherein the thermocouples are each located within a perimeter of a corresponding one of the transistors.

3. The integrated circuit of claim 1 wherein the thermocouples are each located in an isolation street between nearest neighbor transistors.

4. The integrated circuit of claim 1 wherein the transistors are power transistors.

5. The integrated circuit of claim 1 wherein the thermocouples are each junction isolated from the transistors.

6. The integrated circuit of claim 1 wherein the thermocouples are each isolated from the transistors by a corresponding deep trench isolation structure.

7. The integrated circuit of claim 1 wherein the thermocouples each include an n-type thermopile and a p-type thermopile electrically connected in series with the n-type thermopile.

8. An integrated circuit, comprising:
a transistor formed in or over a semiconductor substrate and having a plurality of layers including at least one p-type layer and at least one n-type layer; and
a thermocouple comprising a p-thermopile and an n-thermopile that are each electrically isolated from the transistor and located adjacent the transistor, wherein:
the p-thermopile comprises a p-type thermoelectric body formed in a p-type one or more of the plurality of layers; and
the n-thermopile comprises an n-type thermoelectric body formed in an n-type one or more of the plurality of layers.

9. The integrated circuit of claim 8 wherein the p-type and n-type thermoelectric bodies each extend laterally between common first and second locations.

10. The integrated circuit of claim 8 wherein the p-type and n-type thermoelectric bodies are arranged, relative to each other and to the transistor, to experience a same thermal gradient induced by operation of the transistor.

11. The integrated circuit of claim 8 wherein:
the thermocouple comprises a positive terminal and a negative terminal;
the p-type thermopile comprises first and second p-type ohmic connections electrically connected to opposing ends of the p-type thermoelectric body;
the n-type thermopile comprises first and second n-type ohmic connections electrically connected to opposing ends of the n-type thermoelectric body;
the first p-type and n-type ohmic connections are co-located and respectively connected to the positive and negative terminals; and
the second p-type and n-type ohmic connections are co-located and electrically connected.

12. The integrated circuit of claim 11 wherein the temperature differences within the integrated circuit resulting from the transistor operation, and to which the thermocouple is sensitive, are thermal gradients that increase along a direction from the first p-type and n-type ohmic connections to the second p-type and n-type ohmic connections.

13. The integrated circuit of claim 8 wherein:
the p-type and n-type thermoelectric bodies are electrically isolated by at least one trench filled with a dielectric material and extending through ones of the layers to the semiconductor substrate;
the p-type thermoelectric body is a p-doped silicon region formed simultaneously with at least one other p-type feature of the transistor;
the at least one other p-type feature is at least one of a p-type epitaxial layer, a p-type buried layer, a p-type shallow well, a p-type source/drain region, a p-type reduced surface electric field region, and a p-type deep well;
the n-type thermoelectric body is an n-doped silicon region formed simultaneously with at least one other n-type feature of the transistor; and
the at least one other n-type feature is at least one of an n-type buried layer, an n-type deep trench, an n-type shallow well, an n-type source/drain region, an n-type drift region, and an n-type deep well.

14. The integrated circuit of claim 8 wherein:
the p-type and n-type thermoelectric bodies are junction-isolated portions of a silicon region;
the p-type thermoelectric body is a p-doped portion of the silicon region formed simultaneously with at least one other p-type feature of the transistor;
the at least one other p-type feature is at least one of a p-type epitaxial layer, a p-type buried layer, a p-type shallow well, a p-type source/drain region, a p-type reduced surface electric field region, and a p-type deep well;
the n-type thermoelectric body is an n-doped portion of the silicon region formed simultaneously with at least one other n-type feature of the transistor; and
the at least one other n-type feature is at least one of an n-type buried layer, an n-type deep trench, an n-type shallow well, an n-type source/drain region, an n-type reduced surface electric field region, an n-type drift region, and an n-type deep well.

15. A method of manufacturing an integrated circuit, comprising:
forming an array of transistors in or over a semiconductor substrate;
forming a plurality of thermocouples within the array, each thermocouple electrically isolated from the transistors and the semiconductor substrate and from others of the thermocouples; and
configuring the thermocouples to provide an electrical signal responsive to heat flow from an interior portion of the array to a peripheral portion of the array.

16. The method of claim 15 wherein:
forming each thermocouple comprises forming a p-thermopile and an n-thermopile;
forming the p-thermopile comprises forming a p-type thermoelectric body using one or more process steps used to form a p-type feature of the transistors; and
forming the n-thermopile comprises forming an n-type thermoelectric body using one or more process steps used to form an n-type feature of the transistors.

17. The method of claim 15 wherein forming each thermocouple comprises forming a p-thermopile adjacent an n-thermopile, and further comprising:
electrically connecting co-located first ends of the p-thermocouple and the n-thermocouple of each thermocouple;
electrically connecting a negative terminal of a first thermocouple to a positive terminal of a first nearest-neighbor thermocouple; and
electrically connecting a positive terminal of the first thermocouple to a negative terminal of a second nearest-neighbor thermocouple.

18. The method of claim 17 wherein the co-located first ends are located between a central portion of the array and the positive and negative terminals.

19. The method of claim 15 further comprising electrically isolating each thermocouple from the array of transistors with a deep-trench isolation structure.

20. The method of claim 15 wherein the thermocouples are located between nearest-neighbor transistors.
